(19) United States
(12) Patent Application Publication
(10) Pub. No.: US 2026/0228409 A1
(43) Pub. Date: Aug. 6, 2026

(54) SUBSTRATE ROUTING METHOD

(71) Applicant: Advanced Semiconductor Engineering, Inc., Kaohsiung (TW)

(72) Inventors: Chih-Yi HUANG, Kaohsiung (TW); Keng-Tuan CHANG, Kaohsiung (TW); Chen-Chao WANG, Kaohsiung (TW); Ding-Hsun LIN, Hsinchu (TW); Yu-Jen CHEN, Hsinchu (TW); Tsung-Yi HO, Hsinchu (TW)

(73) Assignee: Advanced Semiconductor Engineering, Inc., Kaohsiung (TW)

(21) Appl. No.: 19/044,593

(22) Filed: Feb. 3, 2025

(51) Int. Cl. G06F 30/3947; G06F 30/3953

(52) U.S. Cl. CPC G06F 30/3947; G06F 30/3953

(57) ABSTRACT

A method of a substrate routing is disclosed. The method includes obtaining design information of a substrate, and mitigating a detour of a first net of the substrate and generating a second net of the substrate. The method also includes optimizing a density of the second net of the substrate.

### BACKGROUND

### 1. Field of the Disclosure

The present disclosure generally relates to a substrate routing method.

### 2. Description of the Related Art

What once took days of manual routing can now be accomplished in just a few hours using auto-routing tools. However, the results generated by these tools are often less than ideal and typically require manual cleanup and adjustments. For example, the routing traces produced by auto-routing tools may include detours, redundant bends, crossing nets, or overly dense distributions, all of which can lead to crosstalk and degrade the electrical performance of the substrate. As a result, the final outcomes of the routing may necessitate extensive cleanup, raising the question of whether manual routing might have been the better option from the start.

### SUMMARY

In some arrangements, a method of a substrate routing includes obtaining design information of a substrate, and mitigating a detour of a first net of the substrate and generating a second net of the substrate. The method also includes optimizing a density of the second net of the substrate.

In some arrangements, a method of a substrate routing includes obtaining design information of a substrate, and generating a plurality of nets of two points based on two factors. The method also includes selecting a net from the plurality of nets based on a total length or a number of segments of the plurality of nets.

In some arrangements, a method of a substrate routing includes identifying a dense routing area in a substrate, and identifying a sparse routing area in the substrate adjacent to the dense routing area in the substrate. The method also includes adjusting nets in the dense routing area toward the sparse routing area.

### BRIEF DESCRIPTION OF THE DRAWINGS

Aspects of some arrangements of the present disclosure are best understood from the following detailed description when read with the accompanying figures. It should be noted that various structures may not be drawn to scale, and dimensions of the various structures may be arbitrarily increased or reduced for clarity of discussion.

FIG. 1 illustrates a flow chart of a method for routing a substrate, in accordance with an arrangement of the present disclosure.

FIG. 2 illustrates a substrate circuitry, in accordance with an arrangement of the present disclosure.

FIG. 3A illustrates one or more stages of a process for detour detection, in accordance with an arrangement of the present disclosure.

FIG. 3B illustrates one or more stages of a process for significant detour refinement, in accordance with an arrangement of the present disclosure.

FIG. 3C illustrates one or more stages of a process for slight detour refinement in accordance with an arrangement of the present disclosure.

FIG. 3D illustrates one or more stages of a process for slight detour refinement in accordance with an arrangement of the present disclosure.

FIG. 4A illustrates one or more stages of a process for global and/or local net translation, in accordance with an arrangement of the present disclosure.

FIG. 4B illustrates one or more stages of a process for dense and/or sparse area detection, in accordance with an arrangement of the present disclosure.

FIG. 5 illustrates one or more stages of a process for redundant bends reduction, in accordance with an arrangement of the present disclosure.

FIG. 6 is a block diagram of a substrate routing system in accordance with some embodiments of the present disclosure.

### DETAILED DESCRIPTION

Common reference numerals are used throughout the drawings and the detailed description to indicate the same or similar components. Arrangements of the present disclosure will be readily understood from the following detailed description taken in conjunction with the accompanying drawings.

The following disclosure provides many different arrangements, or examples, for implementing different features of the provided subject matter. Specific examples of components and arrangements are described below to explain certain aspects of the present disclosure. These are, of course, merely examples and are not intended to be limiting. For example, the formation of a first feature over or on a second feature in the description that follows may include arrangements in which the first and second features are formed or disposed in direct contact, and may also include arrangements in which additional features may be formed or disposed between the first and second features, such that the first and second features may not be in direct contact. In addition, the present disclosure may repeat reference numerals and/or letters in the various examples. This repetition is for the purpose of simplicity and clarity and does not in itself dictate a relationship between the various arrangements and/or configurations discussed.

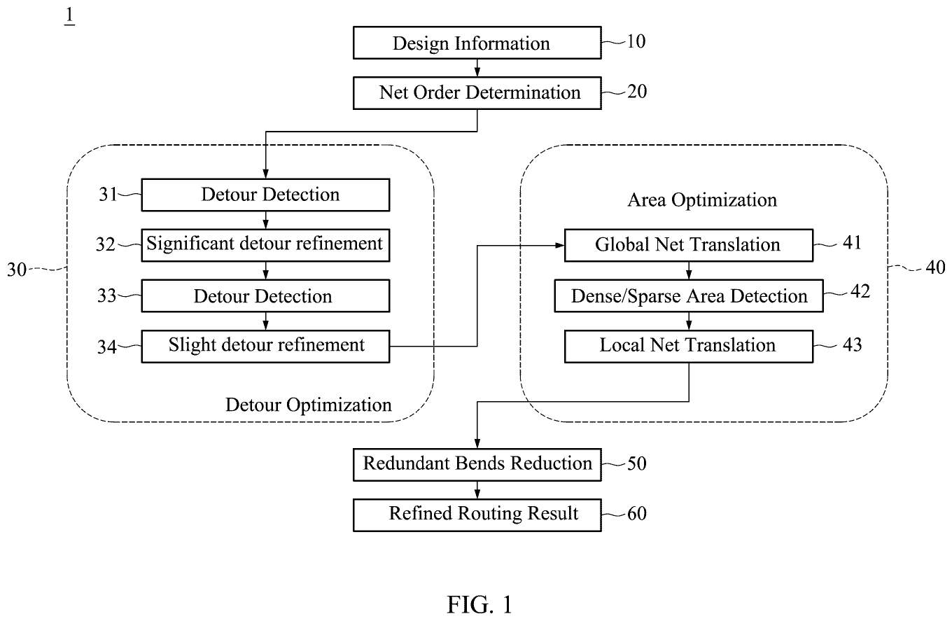

FIG. 1 illustrates a flow chart of a method 1 for routing a substrate, in accordance with an arrangement of the present disclosure. In some arrangements, the substrate may include semiconductor substrates, ceramic substrates, metallized substrates, glass substrates and semiconductor device mounting support such as printed circuit boards and flex circuits.

In some arrangements, the method 1 may be used for routing optimization, while in others, it may be applied to auto-routing optimization. For example, the method 1 may be used to create and/or optimize a substrate circuitry or a substrate circuit design. For example, the method 1 may be used to create and/or optimize the routes or paths among interconnected components of a substrate circuitry. For example, the method 1 may be used to optimize a netlist of a substrate circuitry. For example, the method 1 may be used to optimize a net of a substrate circuitry.

During the circuit design process, a circuit design may be laid out so that the two-dimensional (2D) routes are geometrically positioned relative to one another. A circuit description is then extracted as a netlist, which takes into account precise materials, dielectrics, 3D dimensions, and other factors, modeling the entire circuit as a list of connected nets. A net can refer to a set of electrically connected structures in a circuit that allows signals to travel between components. The component may include a passive device, an active device, an input/output (I/O), etc. In the disclosure, the terms “net,” “wire,” “route,” and “path” can be used interchangeably. A netlist can refer to a textual or graphical representation of the nets and the components in a circuitry. It describes how they are interconnected.

The method 1 begins with operation 10 including obtaining or receiving design information of the substrate circuitry. In some arrangements, the design information may include information or descriptions associated with a net and/or a component to be disposed on the substrate. For example, the design information may include various details such as the sizes, locations, relative distances, and directions of elements like pins, vias, and components. For example, the design information may include various details such as lengths, directions, and signal types of the nets connecting with the above elements.

In some arrangements, the design information may include a netlist. The specific format of design information can vary depending on the electronic design automation (EDA) tool or design environment being used.

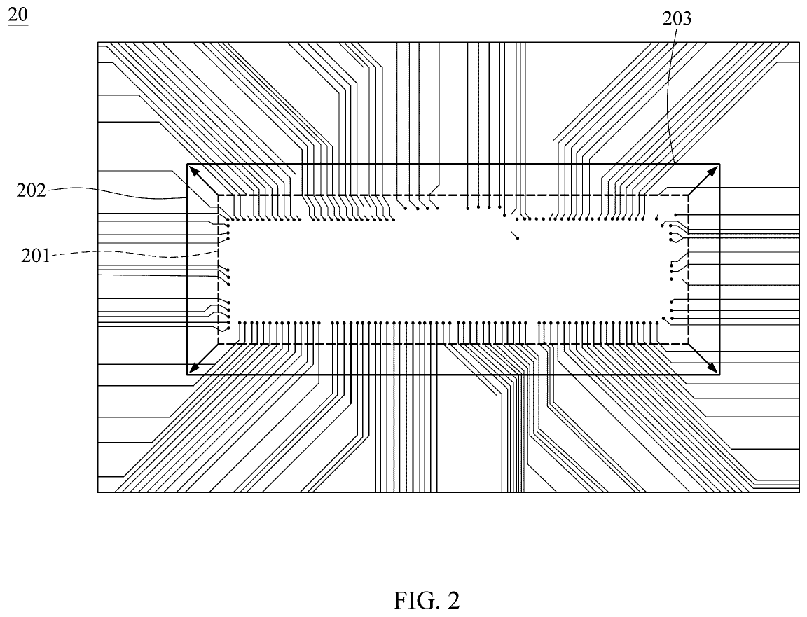

The method 1 continues with operation 20 including determining a net order of the substrate circuitry. Referring to FIG. 2, it illustrates a substrate circuitry, in accordance with an arrangement of the present disclosure. The substrate circuitry may include a component to be disposed on the substrate and nets connected with the component. Each of the nets may include a starting point inside the component area and an end point extending away from the component.

In some arrangements, determining the net order can facilitate smoother refinements in subsequent steps. For example, the net order may determine the processing order of the nets.

In some arrangements, this determination may start with expanding the size of a component boundary (represented by a dotted line 201 in FIG. 2) to create an expanded frame (represented by a solid line 202 in FIG. 2).

Next, the intersection points 203 between the starting points and the end points may be calculated. In some arrangements, calculating the intersection points 203 may involve finding the points at which the nets cross or intersect with the boundary of the expanded frame 203. In some arrangements, calculating the intersection points 203 may involve finding the points at which the nets cross or intersect with the boundary of the expanded frame 203.

Subsequently, the nets may be sorted based on the locations of the intersection points 203. In some arrangements, sorting the nets may be done in various ways, such as by angle or by distance from a reference point.

Then, the net order may be established from the sorted results, either in a clockwise or counterclockwise direction. In some arrangements, establishing the net order may involve arranging the net order in a circular manner based on their intersection points, either moving clockwise or counterclockwise around the expanded frame. For example, the net order may represent the relative locations of the nets.

In some arrangements, if the expanded frame crosses a point on the net between the starting point and the end point, the expanded frame can intersect with the net. On the contrary, when the expanded frame is unable to intersect with the net, there is a possibility that the starting point is not under the component. When the expanded frame is unable to intersect with each net, the quantity of the sorted results does not equal the quantity of the nets. The determination process may be repeated, starting with the creation of an expanded frame of a different size.

In some arrangements, after operation 20, each net of the substrate circuitry may have a designated serial number, and the nets may be identified by a sequence of numbers. In the present disclosure, the serial number may include N−1, N, N+1, and N+2, where N can be any number.

The method 1 continues with operation 30 including detour optimization. Detour can refer to a routing of a net that exceeds the manhattan length. The manhattan length is defined as the shortest path a net can take when it is connected using only segments that are restricted to either the X-axis or the Y-axis. A detoured net may include a plurality of segments.

The operation 30 may include mitigating a detour in the substrate circuitry. For example, the operation 30 may include mitigating a detour of a net of the substrate, and generating an optimized net of the substrate. For example, the operation 30 may include mitigating a detour of a first net of the substrate and generating a second net of the substrate. For example, operation 30 may optimize the substrate circuitry by using nets with a shorter total length or by utilizing nets with fewer segments. For example, the new or optimized nets may include fewer segments or a smaller amount.

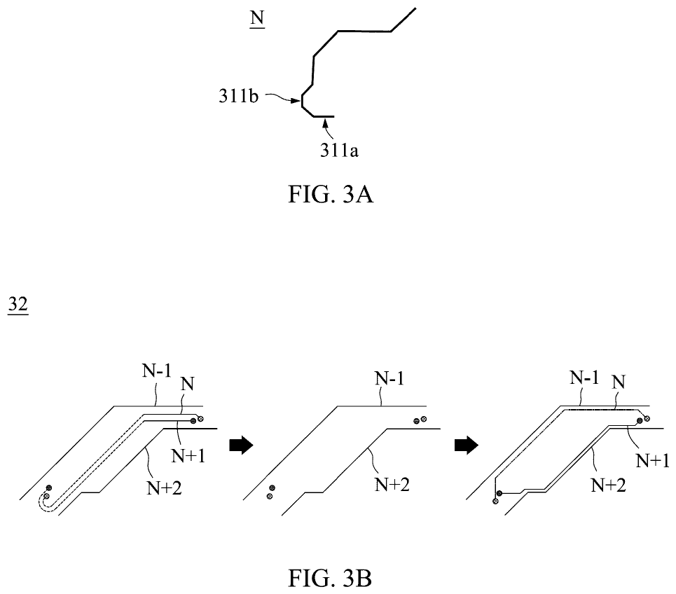

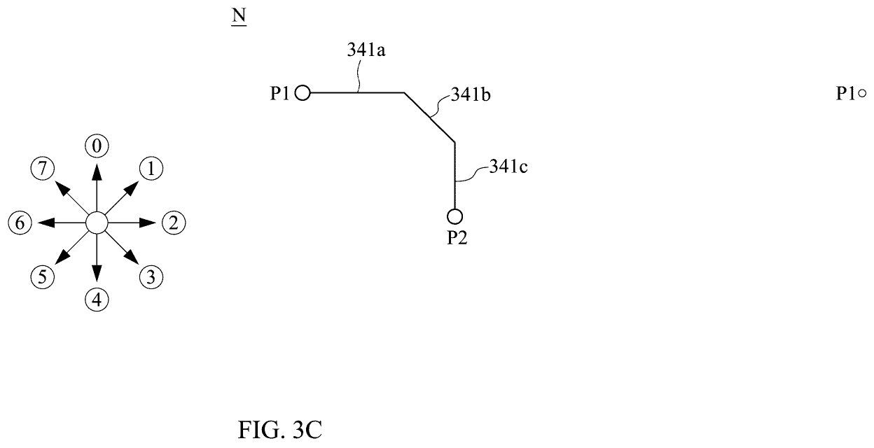

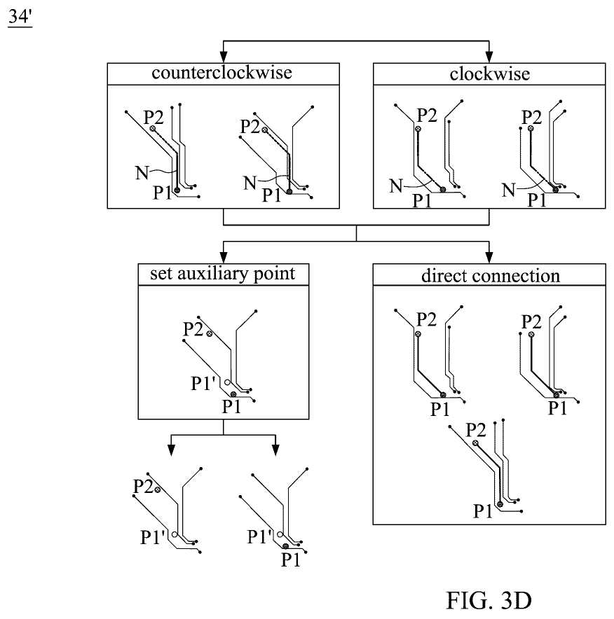

In some arrangements, operation 30 may include sub-operations 31, 32, 33, and 34. The sub-operations 31 and 33 may include detecting the detoured nets. Referring to FIG. 3A, it illustrates one or more stages of a process for detour detection, in accordance with an arrangement of the present disclosure.

The detour detection may be configured to identify significant detours and slight detours. In some arrangements, the significant detours may include significant detoured nets and the slight detours may include slight detoured nets.

In some arrangements, the significant detours can be distinguished from the slight detours by the number of turning points in the net. For example, a net that turns continuously in the same direction more than four times can be classified as a significant detour. Conversely, a net that turns continuously in the same direction fewer than four times can be classified as a slight detour. By making this distinction, the significant detours can be refined before addressing the slight detours.

The detour detection may utilize hybrid detour detection methodologies including: (1) rule-based pattern-based detour detection and (2) object detection-based CenterNet-HarDNet. Initially, the rule-based pattern-based detour detection may be used to identify all potential detoured nets (including the significant detours and the slight detours). Then, the object detection-based CenterNet-HarDNet may be employed to identify the significant detours from the potential detour nets.

The rule-based pattern-based detour detection may be an approach relying on predefined rules and patterns to identify detours. For example, detours can be found by checking the vectors of the segments in a net. For example, detours can be found by checking the relationship between two vectors associated with these segments in a geometric or mathematical context.

For example, the net N may consist of multiple segments, including segments 311a and 311b. The segments 311a and 311b may be perpendicular (or orthogonal) to each other. The lengths of segments 311a and 311b can be evaluated to determine if either segment falls below a specified length threshold. If one of the segments is found to be shorter than this threshold, the segments 311a and 311b will be identified and marked as detoured segments, and the net N may be identified and marked as a detoured net. This process can be continued to assess the other segments of the net N.

The object detection-based CenterNet-HarDNet may be an approach using machine learning techniques, such as object detection algorithms, to identify and classify objects (including detours) in images or video feeds.

The sub-operation 32 may include significant detour refinement. Referring to FIG. 3B, it illustrates one or more stages of a process for significant detour refinement, in accordance with an arrangement of the present disclosure. In FIG. 3B, there are nets N−1, N, N+1, and N+2 in the substrate circuitry. The nets N and N+1 may be identified and marked as detoured nets, as stated in the sub-operation 31.

The significant detour refinement may include a riverside routing method. For example, the significant detour refinement may start with removing one or more nets that have significant detours. For example, the nets N and N+1 are removed.

Next, the adjacent nets of the removed nets are identified. For example, the nets N−1 and N+2 are identified. In addition, the segments of the nets N−1 and N+2 are also identified. The nets N−1 and N+2 may not be identified and marked as detoured nets.

Subsequently, the removed nets may be rerouted along neighboring nets. For example, the net N may be rerouted along the net N−1, and the net N+1 may be rerouted along the net N+2.

By using the riverside routing method, the detours of the nets N and N+1 can be mitigated. The newly routed nets may have a shorter total length or fewer segments than the original nets.

Then, the sub-operation 34, slight detour refinement, may be conducted. Referring to FIG. 3C, it illustrates one or more stages of a process for slight detour refinement, in accordance with an arrangement of the present disclosure. The net N may be identified and marked as a detoured net, as stated in the sub-operation 31. The net N may include a start point P1 and an end point P2. The net N may include a plurality of segments 341a, 341b, and 341c.

The slight detour refinement may convert the routing issue into a sequence modeling issue. For example, the slight detour refinement may utilize reinforcement learning and treat the routing issue as a decision-making process to optimize the detoured nets.

For example, the slight detour refinement may start with converting the net N into a sequence of segments based on a direction factor and a length factor. According to the restrictions of the routing angle, the direction can be divided into eight types, ranging from direction type No. 0 to No. 7. Using the previously determined window size as a reference, the length of each segment can be represented as a number between 0 and 1. For example, the segment 341a can be represented as (2, 0.4), where 2 indicates that segment 341a is directed toward direction type No. 2, and 0.4 represents the standardized length. For example, the segments 341a, 341b, and 341c of the net N can be presented as a sequence: [(2, 0.4), (3, 0.3), (4, 0.25)].

Then, the sequence may be fed into a decision transformer model. The decision transformer model may take actions while considering the interactions between the direction factor and the length factor. For example, the decision transformer model may predict or generate a plurality of nets of two points while considering the interactions between the direction factor and the length factor.

Subsequently, the decision transformer model may select a net from the plurality of nets based on a total length and/or number of segments of the plurality of nets. For example, the shortest net and/or the net having the least segments may be selected.

In some arrangements, the sub-operation 34 may be replaced by the sub-operation 34′. Referring to FIG. 3D, it illustrates one or more stages of a process for slight detour refinement, in accordance with an arrangement of the present disclosure. The sub-operation 34′ may include refining the slight detours using a DNN (deep neural network) guided routing method. The sub-operation 34′ may utilize a deep learning model, particularly a neural network, to predict and/or generate the nets.

For example, net N may be identified and marked as a detoured net, as stated in the sub-operation 31. The net N may include a start point P1 and an end point P2. The sub-operation 34′ may start with determining the start point P1 and the end point P2.

Next, a plurality of nets of the start point P1 and the end point P2 may be predicted or generated by the deep learning model. The predicted net may include a plurality of segments. The predicted routing direction can be either counterclockwise or clockwise. The turning angle may be about 45 degrees.

Following the predicted result, if no intersections of the nets are found, a routing path (such as a direct routing path) may be established from the start point to the end point.

If an intersection is present or found, an auxiliary point P1′ may be generated and the routing problem may be divided into two sub-problems: one from the start point P1 to the auxiliary point P1′ and the other from the auxiliary point P1′ to the end point P2. The sub-operation 34′may be repeated.

The method 1 continues with operation 40 including area optimization. The operation 40 may include addressing the dense routing area issue. The method 1 prioritizes resolving the detour issue first, and then addresses the dense routing area issue.

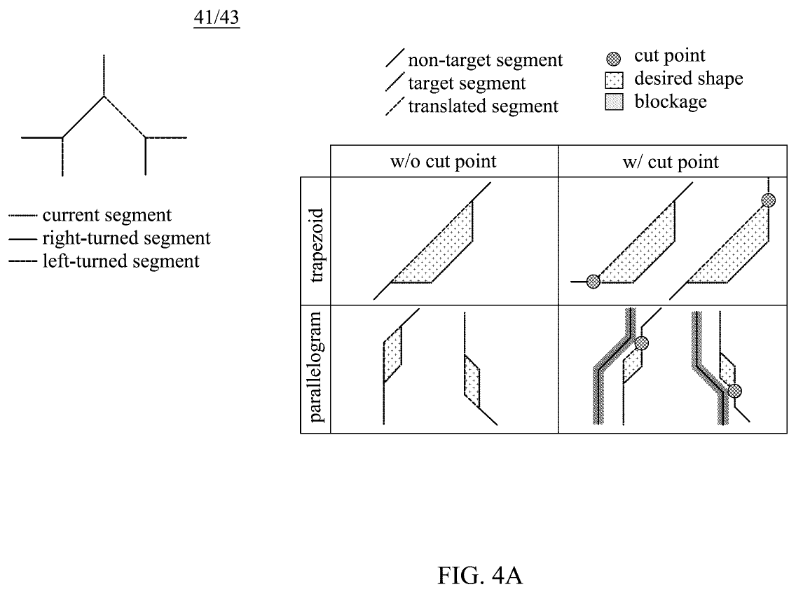

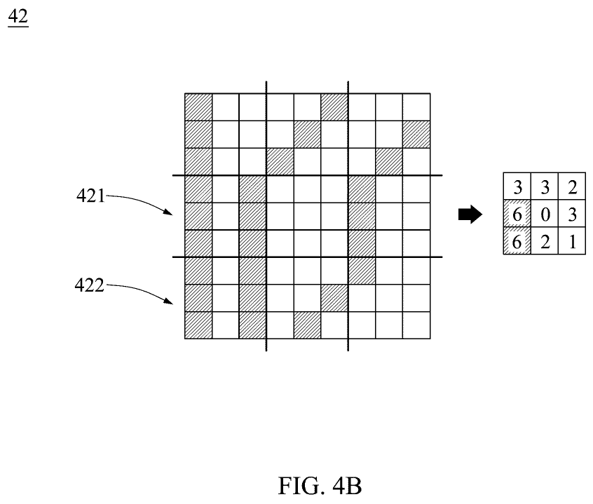

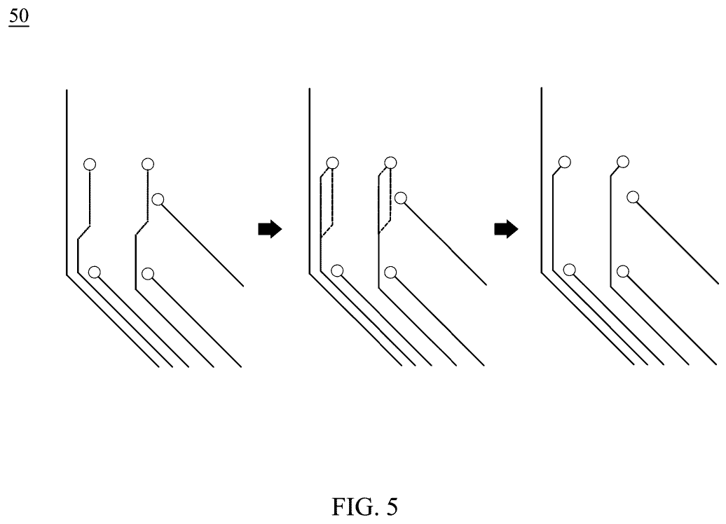

In some arrangements, operation 40 may include sub-operations 41, 42, and 43. The sub-operation 41 may include global net translation. Referring to FIG. 4A, it illustrates one or more stages of a process for global net translation, in accordance with an arrangement of the present disclosure.

The global net translation may include a rough refinement of the dense routing area. The rough refinement may start with selecting a segment in a net. For example, the current segment may be selected.

Next, three consecutive segments may be generated from the selected segment. The predicted routing direction can be either counterclockwise or clockwise. The turning angle may be about 45 degrees. For example, the right-turned segments and the left-turned segments may be generated, and connected with the selected segment.

Next, a predicted pattern (or a shape) of the three consecutive segments may be determined. The pattern may include a trapezoid or a parallelogram. For example, the three consecutive segments may form a trapezoid with a translated segment. For example, the three consecutive segments may form a parallelogram with a translated segment.

Subsequently, the desired pattern may be created if the desired pattern can be constructed without an auxiliary point (such as a cut point).

In some arrangements, an auxiliary point may be established if it is not feasible to directly construct the desired pattern. The auxiliary point may be set based on nearby segments, considering the net spacing. Finally, the desired pattern may be constructed and followed by a net translation step.

After the sub-operation 41, the sub-operation 42 may be conducted. The sub-operation 42 may include dense/sparse area detection. Referring to FIG. 4B, it illustrates one or more stages of a process for dense and/or sparse area detection, in accordance with an arrangement of the present disclosure.

The dense/sparse area detection may start with dividing a routing area in the substrate circuitry into several blocks. For example, the routing area in FIG. 4B may be divided into night blocks including the blocks 421 and 422. Each block may include pixels, either exclusive of nets or including nets. For example, the white pixels (or empty pixels) may be exclusive of nets, while the black pixels (or filled pixels) may include nets.

Next, the numbers of black pixels in each block may be counted or calculated. The block may be identified as a dense routing area if the numbers of the black pixels exceed a specified threshold, or otherwise, the block may be identified as a sparse routing area. For example, the number of black pixels in the blocks 421 and 422 exceeds the specified threshold of 6. Therefore, the blocks 421 and 422 may be identified as dense routing areas.

Subsequently, the contiguous dense routing areas may be combined into a merged area. For example, the blocks 421 and 422 may be combined into a merged area.

The sub-operation 43 may include local net translation. In some arrangements, the local net translation may be conducted through a process identical to that of the global net translation.

In some arrangements, the local net translation may include a detailed refinement of the dense routing area. For example, nets in the dense routing area may be moved or adjusted toward the sparse routing area. For example, a boundary of the merged area that is perpendicular to a routing direction may be expanded until it encounters another dense routing area or reaches a design boundary. For example, a boundary can be extended outward until it either intersects with another dense routing area or reaches the limits defined by the overall design boundary.

The boundary expansion process allows for the optimization of routing paths, ensuring that the newly created space can accommodate additional routing needs while maintaining the integrity of the existing design framework.

The method 1 continues with operation 50 including redundant bends reduction. Referring to FIG. 5, it illustrates one or more stages of a process for redundant bends reduction, in accordance with an arrangement of the present disclosure.

To address this issue and eliminate the unnecessary bends, a process identical to that of the global net translation may be applied to convert the redundant bends into straight lines.

The method 1 continues with operation 60 including outputting the refined routing result.

This disclosure presents a hybrid refinement strategy that combines hybrid detour refinement methodologies with decision transformer architecture, which utilize the reinforcement learning (RL) and treat the problem as a decision-making process to optimize detour paths. Additionally, deep learning architectures are employed to classify patches based on their density of routing areas and to identify net crossings. The approach enhances detours, optimizes dense routing areas, and reduces redundant bends. The proposed method achieves an average detour reduction of 55% and improves routing area distribution by 32%.

As should be apparent from the foregoing description, the various techniques and processes introduced above can be used to improve the operation and processing of electronic design automation (EDA) software and related systems.

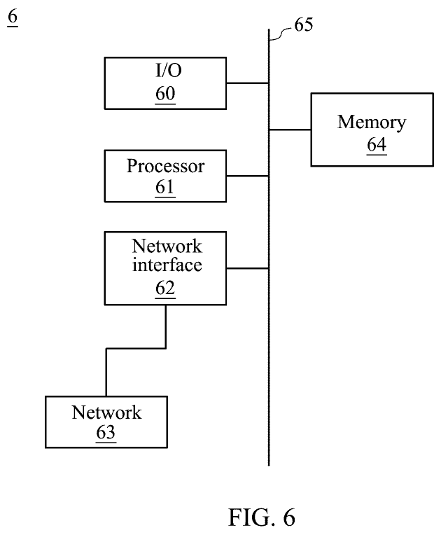

FIG. 6 is a block diagram of a substrate routing system 6 in accordance with some embodiments of the present disclosure.

In some embodiments, the substrate routing system 6 may include an I/O interface 60, a processor 61, a network interface 62, a memory 64, and a bus 65.

In some embodiments, the I/O interface 60 may be coupled to an external circuitry. In some embodiments, the substrate routing system 6 may be configured to receive information through the I/O interface 60. The information received through the I/O interface 60 may include one or more of instructions, data, design rules, process performance histories, target ranges, set points, and/or other parameters for processing by the processor 61. The information may be transferred to the processor 61 via the bus 65. The information may be stored in the memory 64.

In one or more embodiments, the I/O interface 60 may include a keyboard, keypad, mouse, trackball, trackpad, touchscreen, and/or cursor direction keys for communicating information and commands to the processor 61.

In some embodiments, the processor 61 may be configured to execute instructions (which may be referred to as computer program code) encoded in the memory 64 in order to cause the processor 61 to be usable for performing a portion or all of method 1 described herein.

In some embodiments, the processor 61 may be a central processing unit (CPU), a multiprocessor, a distributed processing system, an application specific integrated circuit (ASIC), and/or a suitable processing unit. The processor 61 may be embodied in a standalone die or as a discrete integrated circuit.

In some embodiments, the network interface 62 may be coupled to the processor 61 through the bus 65. The network interface 62 may allow the substrate routing system 6 to communicate with network 63, to which one or more other computer systems are connected. Network interface 63 may include wireless network interfaces such as BLUETOOTH, WIFI, WIMAX, GPRS, or WCDMA; or wired network interfaces such as ETHERNET, USB, or IEEE-1364.

In some embodiments, the memory (which may be referred to as a non-transitory, computer-readable storage medium) 64, amongst other things, may be encoded with, i.e., stores, instructions (or computer program code), such as a set of executable instructions. In some embodiments, the memory 64 may be an electronic, magnetic, optical, electromagnetic, infrared, and/or a semiconductor system (or apparatus or device). For example, the memory 64 may include a semiconductor or solid-state memory, a magnetic tape, a removable computer diskette, a random access memory (RAM), a read-only memory (ROM), a rigid magnetic disk, and/or an optical disk. In one or more embodiments using optical disks, the memory 64 may include a compact disk-read only memory (CD-ROM), a compact disk-read/write (CD-R/W), and/or a digital video disc (DVD).

Each function mentioned in the disclosure or FIGS. can generally be implemented as instructional logic (e.g., as instructions stored on non-transitory machine-readable media), as hardware logic, or as a combination of these, depending on the embodiment or specific design. Each function mentioned in the disclosure or FIGS. can be stored and/or executed by a single computer or processor; in other cases, it can be stored and/or executed on a distributed basis, e.g., using one or more servers, clients, or application-specific devices, whether collocated or remote from each other.

Examples may further relate to a computer program containing program code for performing one or more of the above methods when the computer program is executed on a computer or processor. Steps, operations, or processes of the various above-described methods may be performed by programmed computers or processors. Examples may also encompass program storage devices such as digital data storage media, which are machine-, processor-, or computer-readable and encode machine-executable, processor-executable, or computer-executable programs of instructions. The instructions perform or cause the performance of some or all of the actions of the above-described methods.

Spatial descriptions, such as “above,” “below,” “up,” “left,” “right,” “down,” “top,” “bottom,” “vertical,” “horizontal,” “side,” “higher,” “lower,” “upper,” “over,” “under,” and so forth, are indicated with respect to the orientation shown in the figures unless otherwise specified. It should be understood that the spatial descriptions used herein are for purposes of illustration only, and that practical implementations of the structures described herein can be spatially arranged in any orientation or manner, provided that the merits of arrangements of this disclosure are not deviated from by such an arrangement.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, a first numerical value can be deemed to be “substantially” the same or equal to a second numerical value if the first numerical value is within a range of variation of less than or equal to ±10% of the second numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, “substantially” perpendicular can refer to a range of angular variation relative to 90°that is less than or equal to ±10°, such as less than or equal to ±5°, less than or equal to ±4°, less than or equal to ±3°, less than or equal to ±2°, less than or equal to ±1°, less than or equal to ±0.5°, less than or equal to ±0.1°, or less than or equal to ±0.05°.

Two surfaces can be deemed to be coplanar or substantially coplanar if a displacement between the two surfaces is no greater than 5 μm, no greater than 2 μm, no greater than 1 μm, or no greater than 0.5 μm. A surface can be deemed to be substantially flat if a displacement between a highest point and a lowest point of the surface is no greater than 5 μm, no greater than 2 μm, no greater than 1 μm, or no greater than 0.5 μm.

As used herein, the singular terms “a,” “an,” and “the” may include plural referents unless the context clearly dictates otherwise.

As used herein, the terms “conductive,” “electrically conductive” and “electrical conductivity” refer to an ability to transport an electric current. Electrically conductive materials typically indicate those materials that exhibit little or no opposition to the flow of an electric current. One measure of electrical conductivity is Siemens per meter (S/m). Typically, an electrically conductive material is one having a conductivity greater than approximately 104 S/m, such as at least 105 S/m or at least 106 S/m. The electrical conductivity of a material can sometimes vary with temperature. Unless otherwise specified, the electrical conductivity of a material is measured at room temperature.

Additionally, amounts, ratios, and other numerical values are sometimes presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range is explicitly specified.

While the present disclosure has been described and illustrated with reference to specific arrangements thereof, these descriptions and illustrations are not limiting. It should be understood by those skilled in the art that various changes may be made and equivalents may be substituted without departing from the true spirit and scope of the present disclosure as defined by the appended claims. The illustrations may not be necessarily drawn to scale. There may be distinctions between the artistic renditions in the present disclosure and the actual apparatus due to manufacturing processes and tolerances. There may be other arrangements of the present disclosure which are not specifically illustrated. The specification and drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations of the present disclosure.

What is claimed is:

1. A method of a substrate routing, comprising:
obtaining design information of a substrate;
mitigating a detour of a first net of the substrate and generating a second net of the substrate; and
optimizing a density of the second net of the substrate.

2. The method of claim 1, wherein the design information includes a netlist.

3. The method of claim 1, further comprising:
determining a net order of the substrate.

4. The method of claim 3, wherein determining the net order of the substrate includes:
expanding a boundary of a component to be disposed on the substrate to create an expanded frame;
calculating intersection points of nets that intersect with the expanded frame; and
establishing the net order in a clockwise or counterclockwise direction.

5. The method of claim 1, wherein a length of the second net of the substrate is shorter than a length of the first net of the substrate.

6. The method of claim 1, wherein a segment number of the second net of the substrate is less than a segment number of the first net of the substrate.

7. The method of claim 1, wherein mitigating the detour of the first net of the substrate and generating the second net of the substrate further comprises:
performing a significant detour refinement; and
performing a slight detour refinement.

8. The method of claim 7, wherein performing the significant detour refinement further comprises:
identifying the first net as a detoured net;
removing the detoured net; and
rerouting a third net along a neighboring net.

9. The method of claim 7, wherein performing the slight detour refinement further comprises:
converting the first net into a sequence of segments based on a direction factor and a length factor.

10. The method of claim 9, wherein performing the slight detour refinement further comprises:
generating the second net shorter than the first net or having less segments than the first net.

11. The method of claim 7, wherein performing the slight detour refinement further comprises:
determining a start point and an end point of the first net;
generating a predicted routing direction; and
establishing a routing path if no intersection is found.

12. The method of claim 11, wherein the routing path includes a plurality of segments.

13. The method of claim 11, wherein performing the slight detour refinement further comprises:
establishing an auxiliary point if an intersection is found.

14. A method of a substrate routing, comprising:
obtaining design information of a substrate;
generating a plurality of nets of two points based on two factors; and
selecting a net from the plurality of nets based on a total length or a number of segments of the plurality of nets.

15. The method of claim 14, wherein the two factors include a direction factor and a length factor.

16. The method of claim 14, wherein generating the plurality of nets of two points further comprises:
presenting each net from the plurality of nets as a sequence of segments, wherein each segment consists of two factors.

17. The method of claim 14, further comprising:
identifying detoured nets; and
classifying the detoured nets into significant detoured nets and slight detoured nets.

18. A method of a substrate routing, comprising:
identifying a dense routing area in a substrate;
identifying a sparse routing area in the substrate adjacent to the dense routing area in the substrate; and
adjusting nets in the dense routing area toward the sparse routing area.

19. The method of claim 18, wherein identifying the dense routing area in the substrate further comprises:
dividing a routing area in the substrate into several blocks;
counting numbers of black pixels in each block; and
identifying a block as the dense routing area if the numbers of black pixels exceed a specified threshold.

20. The method of claim 18, further comprising:
merging contiguous dense routing areas as a merged area.
